(19) United States
(12) Patent Application Publication
(10) Pub. No.: US 2024/0276686 A1
(43) Pub. Date: Aug. 15, 2024

(54) POWER CONVERTER FOR RAILWAY VEHICLE

(71) Applicant: Mitsubishi Electric Corporation, Chiyoda-ku, Tokyo (JP)

(72) Inventor: Kosuke KONAGA, Tokyo (JP)

(73) Assignee: Mitsubishi Electric Corporation, Chiyoda-ku, Tokyo (JP)

(21) Appl. No.: 18/569,730

(22) PCT Filed: Aug. 19, 2021
(86) PCT No.: PCT/JP2021/030331

§ 371 Date: Dec. 13, 2023

(51) Int. Cl. H05K 7/20; B60L 15/00

(52) U.S. Cl. CPC H05K 7/20945; B60L 15/007; H05K 7/20909; B60L 2200/26; B60L 2210/40; B60L 2240/525

(57) ABSTRACT

A power converter for a railway vehicle includes: an inverter that converts direct-current power into alternating-current power for a driving motor; and a control unit that controls operation of the inverter. The inverter includes: a power module on which a plurality of switching elements are mounted; a cooler that cools the power module; and a cooling blower that supplies cooling air to the cooler. The control unit controls rotational speed of the cooling blower on the basis of first information relating to an increase in temperature of the power module.

### FIELD

The present disclosure relates to a power converter for a railway vehicle. The power converter is installed in a railway vehicle and performs required power conversion.

### BACKGROUND

As one of the power converters for railway vehicles, there is an inverter that supplies power to a plurality of driving motors mounted on trucks of an electric motor vehicle. Further, in a power converter for a railway vehicle that travels in an alternating-current section, a converter is added for once converting alternating-current power, which is received from an alternating-current overhead contact line, into a direct current and supplying the direct current to an inverter.

Furthermore, as described in Patent Literature 1, in order to reduce the size and weight of the device, the mainstream cooling system of a power converter for a railway vehicle is a forced air cooling system that circulates the external air with a cooling blower, which is provided for cooling purpose, to cool an inverter and a converter.

### CITATION LIST

### Patent Literature

Patent Literature 1: Japanese Patent Application Laid-open No. 2006-025556

### SUMMARY OF INVENTION

### Problem to be Solved by the Invention

Conventionally, as a cooling blower provided for cooling purpose and used for an inverter in a power converter for railway vehicle, a constant speed type cooling blower that rotates at a constant rotational speed is employed. The cooling blower with sufficient performance is selected to ensure that a junction temperature of switching elements included in the inverter does not exceed a specified value. However, in the cooling blower of this kind of constant speed type, the inverter is excessively cooled when the inverter is not in operation. Therefore, there is a problem in that a temperature fluctuation range of the switching elements becomes large and heat stress that the switching elements are subjected to becomes large.

The present disclosure has been made in view of the above, and an object of the present disclosure is to obtain a power converter for a railway vehicle capable of reducing the heat stress that switching elements are subjected to.

### Means to Solve the Problem

In order to solve the above-described problem and achieve the object, a power converter for a railway vehicle according to the present disclosure is installed in a railway vehicle and performs required power conversion. The power converter for a railway vehicle includes: an inverter that converts direct-current power into alternating-current power for a driving motor; and a control unit that controls operation of the inverter. The inverter includes: a power module on which a plurality of switching elements are mounted; a cooler that cools the power module; and a cooling blower that supplies cooling air to the cooler. The control unit controls rotational speed of the cooling blower on the basis of first information relating to an increase in temperature of the power module.

### EFFECTS OF THE INVENTION

The power converter for a railway vehicle according to the present disclosure can obtain an effect whereby the heat stress that the switching elements are subjected to can be reduced.

### BRIEF DESCRIPTION OF DRAWINGS

FIG. 1 is a diagram illustrating an exemplary configuration of a power converter for a railway vehicle according to a first embodiment.

FIG. 2 is a flowchart provided for describing operation of a control unit in the first embodiment.

FIG. 3 is a diagram illustrating an example of a variation of an input circuit unit illustrated in FIG. 1.

FIG. 4 is a diagram illustrating an exemplary configuration of a power converter for a railway vehicle according to a second embodiment.

FIG. 5 is a first diagram provided for describing operation of a calculation unit in the second embodiment.

FIG. 6 is a second diagram provided for describing the operation of the calculation unit in the second embodiment.

FIG. 7 is a diagram illustrating an exemplary configuration of a power converter for a railway vehicle according to a third embodiment.

FIG. 8 is a first diagram provided for describing operation of a calculation unit in the third embodiment.

FIG. 9 is a second diagram provided for describing the operation of the calculation unit in the third embodiment.

FIG. 10 is a block diagram illustrating an example of a hardware configuration that implements functions of control units in the first to third embodiments.

FIG. 11 is a block diagram illustrating another example of a hardware configuration that implements the functions of the control units in the first to third embodiments.

### DESCRIPTION OF EMBODIMENTS

Hereinafter, a power converter for a railway vehicle according to embodiments of the present disclosure will be described in detail with reference to the accompanying drawings. Note that the embodiments described below are examples, and the scope of the present disclosure is not limited to the following embodiments. In addition, in the following description, physical connection and electrical connection are not distinguished from each other, and are simply referred to as “connection”. That is, the term “connection” includes both a case where constituent elements are directly connected to each other and a case where constituent elements are indirectly connected to each other via another constituent element.

### First Embodiment

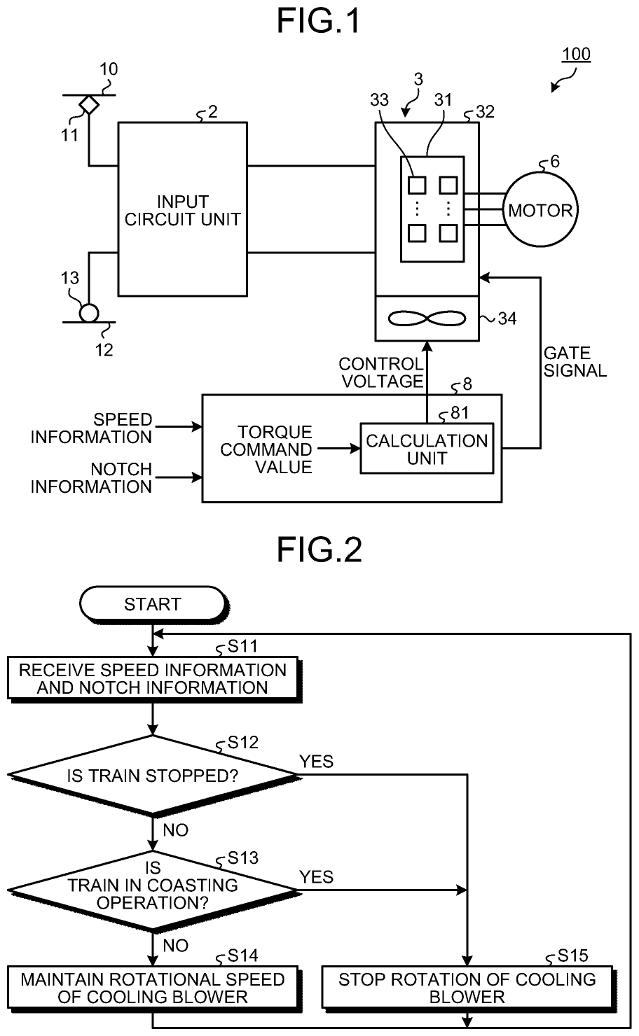

FIG. 1 is a diagram illustrating an exemplary configuration of a power converter 100 for a railway vehicle according to a first embodiment. The power converter 100 for a railway vehicle according to the first embodiment includes an inverter 3 and a control unit 8 that controls the operation of the inverter 3. In FIG. 1, the inverter 3 has an input end connected to an input circuit unit 2 and an output end connected to at least one driving motor 6.

The input circuit unit 2 includes at least a switch, a filter capacitor, and a filter reactor. The input circuit unit 2 has one end connected to an overhead contact line 10 via a power collector 11 and another end connected to rails 12 at the ground potential via wheels 13. Direct-current power or alternating-current power supplied from the overhead contact line 10 is input to the one end of the input circuit unit 2 via the power collector 11. A direct-current voltage of the direct-current power generated at an output end of the input circuit unit 2 is applied to the inverter 3.

The inverter 3 includes a power module 31, a cooler 32, and a cooling blower 34. A plurality of switching elements 33 are mounted on the power module 31. The switching elements 33 generate heat by a switching operation. As a result, the temperature of the power module 31 increases. The cooler 32 cools the power module 31, the temperature of which has increased. The cooling blower 34 supplies cooling air to the cooler 32 to cool the cooler 32.

The control unit 8 generates a gate signal for switching-driving the switching elements 33 on the basis of a known control configuration, and outputs the gate signal to the inverter 3. The switching elements 33 perform the switching operation in accordance with the gate signal. The current flowing through the switching elements 33 is intermittently controlled by the switching operation of the switching elements 33. As a result, the direct-current power supplied from the input circuit unit 2 is converted into alternating-current power for the driving motor 6. The driving motor 6 is driven by the alternating-current power supplied from the inverter 3, and gives a propulsive force to a train including one or more railway vehicles (not illustrated) .

In addition, the control unit 8 includes a calculation unit 81. Speed information and notch information are input to the control unit 8. A torque command value used in the control unit 8 is input to the calculation unit 81. The speed information can be obtained from a tachometer generator or a train information managing apparatus (not illustrated) mounted on a railway vehicle. In addition, the notch information can be obtained from a master controller or the train information managing apparatus (not illustrated) mounted on the railway vehicle.

The cooling blower 34 is configured such that the rotational speed of the cooling blower 34 can be changed by a control voltage output from the control unit 8. The calculation unit 81 calculates the control voltage on the basis of the speed information and the notch information. Note that the torque command value used when the gate signal is generated may be used instead of the notch information. In this case, the calculation unit 81 calculates the control voltage on the basis of the speed information and the torque command value.

The notch information is input to the control unit 8 as information relating to an increase in temperature of the power module. In addition, the torque command value is input to the calculation unit 81 as information relating to the increase in temperature of the power module. Note that, in the present specification, the information relating to the increase in temperature of the power module is collectively referred to as “first information” in some cases.

Next, operation of a main portion in the first embodiment will be described with reference to FIGS. 1 and 2. FIG. 2 is a flowchart provided for describing operation of the control unit 8 in the first embodiment. Note that in the following description related to FIG. 2, the term “notch information” may be read as the “torque command value”.

First, in step S11, the control unit 8 receives the speed information and the notch information from the outside. The speed information is information relating to the speed of the train driven by the driving motor 6. Next, in step S12, the control unit 8 determines whether or not the train is stopped on the basis of the speed information. In a case where the control unit 8 determines that the train is stopped (step S12, Yes), the process proceeds to step S15. In step S15, control to stop the rotation of the cooling blower 34 is performed. Any method may be used for the control to stop the rotation of the cooling blower 34. The control may be achieved by shutting off an input power supply to the cooling blower 34, by shutting off the control voltage to the cooling blower 34, or by setting the control voltage to zero.

In a case where the control unit 8 determines that the train is not stopped (step S12, No) , the process proceeds to step S13. In step S13, the control unit 8 determines whether or not the train is in a state of coasting operation on the basis of the notch information. In a case where the control unit 8 determines that the train is in a state of coasting operation (step S13, Yes), the process proceeds to step S15 and the processing described above is performed. In a case where the control unit 8 determines that the train is not in a state of coasting operation (step S13, No), the process proceeds to step S14. In step S14, control to maintain the current rotational speed of the cooling blower 34, that is, control to rotate the cooling blower 34 at the commanded rotational speed is performed.

Next, the above processing will be supplemented, and effects of the processing in the first embodiment will be described. As described above, in the power converter 100 for a railway vehicle, the cooling blower 34 with sufficient performance is selected to ensure that a junction temperature of the switching elements 33 included in the inverter 3 does not exceed a specified value. On the other hand, in a case where the train is stopped or the train is in a state of coasting operation, a torque current, which is a current that generates torque, does not flow through the driving motor 6. In this case, when the cooling blower 34 is operated similarly to a case where the train is in a state of power running operation, the switching elements 33 are excessively cooled. On the other hand, as in the first embodiment, by stopping the operation of the cooling blower 34 in a case where the train is in a stopped state or in a coasting operation state, excessive cooling of the switching elements 33 can be prevented. As a result, a fluctuation range of the junction temperature of the switching elements 33 can be reduced, so that the heat stress that the switching elements 33 are subjected to can be reduced. As a result, a decrease in the life of the switching elements 33 can be reduced, so that the life of the switching elements 33 can be extended.

Although the rotation of the cooling blower 34 is stopped in the process of step S15 described above, the cooling blower 34 may be rotated at a rotational speed lower than the specified value such that the switching elements 33 are not excessively cooled. Even in this case, the effects described above can be obtained.

In addition, in the processing in the first embodiment, the rotation of the cooling blower 34 is stopped during the coasting operation that occupies a relatively large amount of time in a train operation. Accordingly, an effect can be obtained that the power consumption can be reduced as compared with the case of using a conventional cooling blower of a constant speed type.

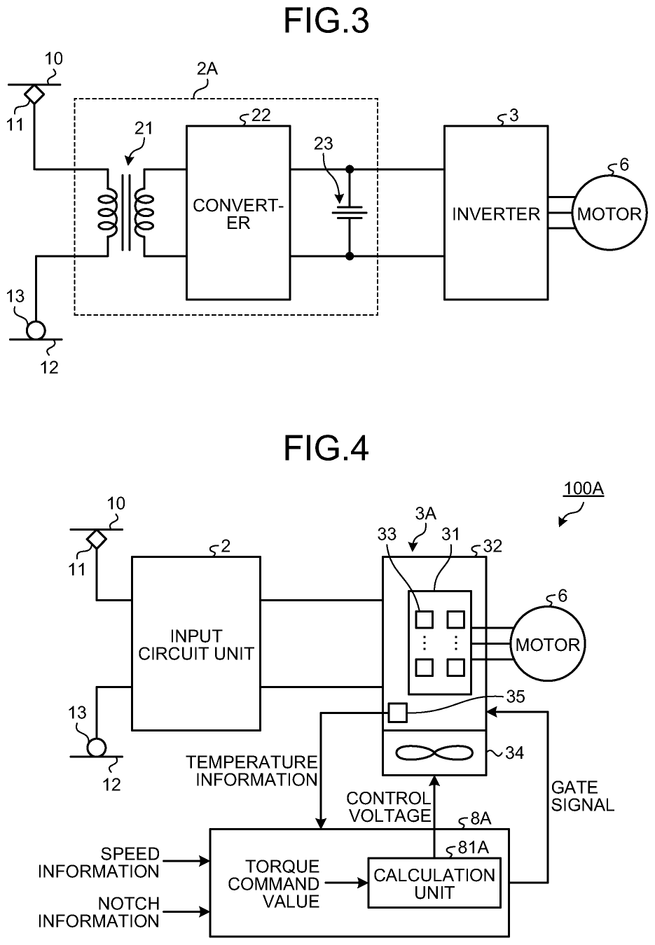

FIG. 3 is a diagram illustrating an example of a variation of the input circuit unit 2 illustrated in FIG. 1. In FIG. 3, an input circuit unit 2A is illustrated as an example of a case in which the overhead contact line 10 is an alternating-current overhead contact line. The input circuit unit 2A includes a traction transformer 21, a converter 22, and a filter capacitor 23. The traction transformer 21 steps down an alternating-current voltage received via the power collector 11 and applies the alternating-current voltage to the converter 22. The converter 22 converts the stepped-down alternating-current voltage into a direct-current voltage and applies the direct-current voltage to the inverter 3. The filter capacitor 23 smooths the direct-current voltage output from the converter 22 so as to reduce a ripple of the voltage applied to the inverter 3.

Similarly to the inverter 3, the converter 22 is a power converter including a power module on which a plurality of switching elements are mounted. In addition, as described above, the mainstream cooling system of the converter 22 is a forced air cooling system that cools a power module with a cooling blower, similarly to the inverter 3. Furthermore, the converter 22 is a power converter that supplies operation power to the inverter 3. Accordingly, the temperature of the switching elements increases in a case where the train is in a state of power running operation and the temperature of the switching elements decreases in a case where the train is in a stopped state or in a coasting operation state. Therefore, by applying the control method described above also to the converter 22, the effects similar to those of the inverter 3 can be obtained. Note that, in the present specification, the power module of the converter 22 is referred to as a “second power module” in some cases in order to distinguish the power module of the converter 22 from the power module 31 of the inverter 3. In addition, speed information and notch information used to control the operation of the cooling blower that cools the second power module are referred to as “second information” in some cases. That is, the second information is information relating to an increase in temperature of the second power module.

As has been described above, according to the power converter for a railway vehicle of the first embodiment, the control unit that controls the operation of the cooling blower controls the rotational speed of the cooling blower in order to reduce the heat stress that the switching elements are subjected to on the basis of the first information relating to the increase in temperature of the power module. As a result, a decrease in the life of the switching elements can be reduced, which enables the life of the switching elements to be extended.

Note that the above control can be implemented by stopping the rotation of the cooling blower when the train is in a coasting operation or in a stopped state. The junction temperature of the switching elements increases when the train is in power running during which a torque current flows, and decreases when the train is in a coasting operation and in a stopped state during each of which a torque current does not flow. Therefore, by stopping the rotation of the cooling blower when the train is in a coasting operation and in a stopped state, the temperature fluctuation range is reduced by an amount of the decrease in junction temperature of the switching elements. As a result, the heat stress that the switching elements are subjected to can be reduced, which enables the life of the switching elements to be extended.

### Second Embodiment.

FIG. 4 is a diagram illustrating an exemplary configuration of a power converter 100A for a railway vehicle according to a second embodiment. As compared with the power converter 100 for a railway vehicle illustrated in FIG. 1, in FIG. 4, the inverter 3 is replaced with an inverter 3A, and the control unit 8 is replaced with a control unit 8A. In the inverter 3A, a temperature sensor 35 is added. A detection value detected by the temperature sensor 35 is input to the control unit 8A as temperature information. In addition, in the control unit 8A, the calculation unit 81 is replaced with a calculation unit 81A. Other configurations are identical or equivalent to those in the power converter 100 for a railway vehicle, and the constituent elements identical or equivalent to those in the power converter 100 are denoted by like reference numerals and detailed description thereof will be omitted.

An example of the temperature sensor 35 is a thermistor. The temperature sensor 35 detects a temperature of the power module 31, a temperature of the cooler 32, or the ambient temperature thereof. The calculation unit 81A calculates the control voltage on the basis of the speed information, the notch information, and the temperature information. The temperature information is another example of the first information. Note that the torque command value may be used instead of the notch information. In this case, the calculation unit 81A calculates the control voltage on the basis of the speed information, the torque command value, and the temperature information.

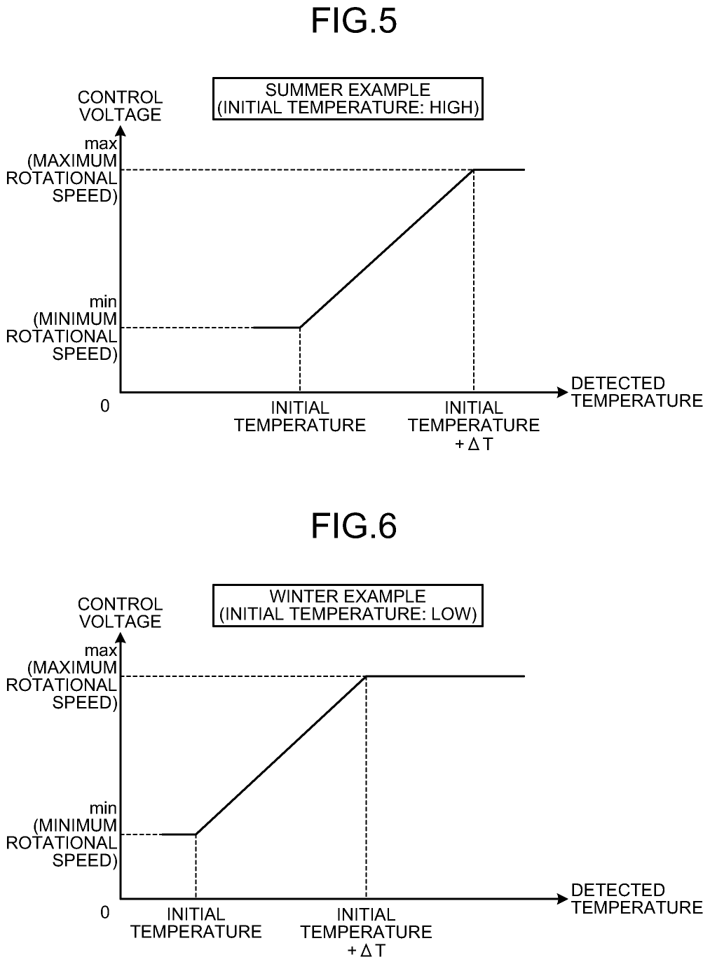

Next, operation of a main portion in the second embodiment will be described with reference to FIGS. 5 and 6. FIG. 5 is a first diagram provided for describing operation of the calculation unit 81A in the second embodiment. FIG. 6 is a second diagram provided for describing the operation of the calculation unit 81A in the second embodiment.

In FIGS. 5 and 6, the horizontal axis indicates a detected temperature that is a detection value of the temperature sensor 35, and the vertical axis indicates the control voltage that changes according to the detected temperature. As illustrated in FIGS. 5 and 6, the control voltage takes a minimum value at an initial temperature, and increases up to a maximum value as the detected temperature increases. The initial temperature is an initial value of the detected temperature, which is detected when the inverter 3A stars its operation at the start of the day. FIG. 5 is an example in summer when the initial temperature is high, and FIG. 6 is an example in winter when the initial temperature is low. In the example in summer illustrated in FIG. 5, the initial temperature is made to correspond to a minimum rotational speed, and initial temperature+ΔT is made to correspond to a maximum rotational speed. In addition, in the example in winter illustrated in FIG. 6, the initial temperature is made to correspond to the minimum rotational speed, and initial temperature+ΔT is made to correspond to the maximum rotational speed. Here, ΔT represents an optional temperature.

Japan is a country with large differences in temperature change depending on the seasons. In addition, Japan has an elongated land extending in the north-south direction, so that differences in temperature change are also large depending on the regions. Therefore, if the change rate at the time of increasing or decreasing the rotational speed is fixed, a large difference occurs in temperature fluctuation range of the cooler 32 due to differences in temperature change between seasons or between regions. On the other hand, as the examples in FIGS. 5 and 6, by determining the change rate at the time of increasing or decreasing the rotational speed of the cooling blower 34 on the basis of the initial temperature, dependency on differences in temperature change between seasons and between regions can be reduced.

Note that, in FIGS. 5 and 6, examples are illustrated in each of which the initial temperature is made to correspond to the minimum rotational speed of the cooling blower 34, but the present disclosure is not limited to these examples. In a case where an operation time is long like an electric railcar in the city, a first temperature that is an optional temperature higher than the initial temperature may be defined and the first temperature may be made to correspond to the minimum rotational speed of the cooling blower 34.

As has been described above, according to the power converter for a railway vehicle of the second embodiment, the inverter includes the temperature sensor that detects the temperature of the power module or the cooler. The control unit determines the change rate at the time of increasing or decreasing the rotational speed of the cooling blower on the basis of the initial value of the temperature information detected by the temperature sensor. In this way, dependency on differences in temperature change between seasons and between regions can be reduced.

### Third Embodiment.

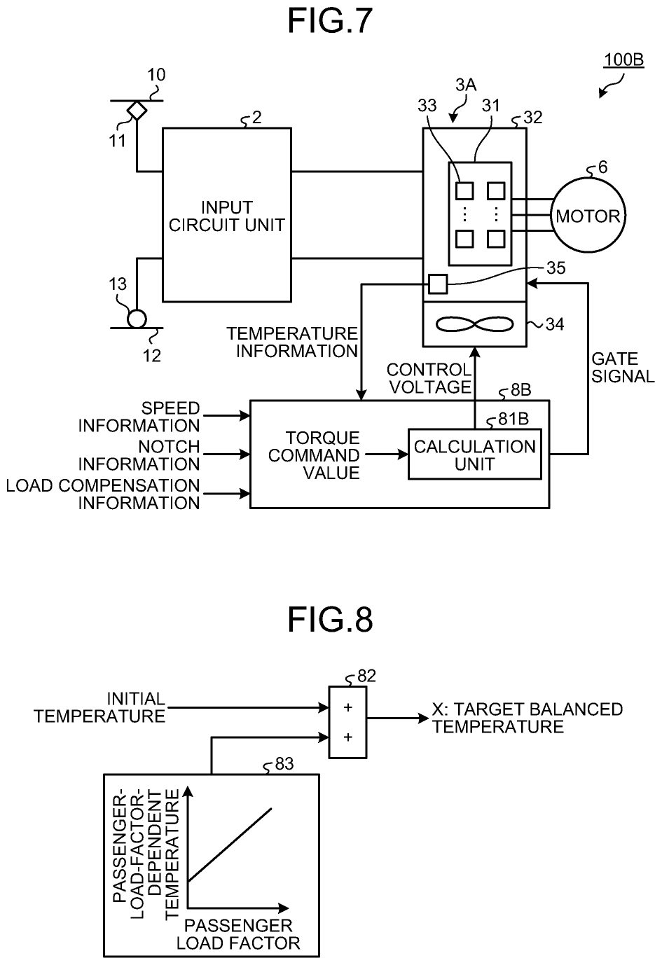

FIG. 7 is a diagram illustrating an exemplary configuration of a power converter 100B for a railway vehicle according to a third embodiment. As compared with the power converter 100A for a railway vehicle illustrated in FIG. 4, in FIG. 7, the control unit 8A is replaced with a control unit 8B. In the control unit 8B, the calculation unit 81A is replaced with a calculation unit 81B. Load compensation information is input to the control unit 8B. Other configurations are identical or equivalent to those in the power converter 100 for a railway vehicle, and the constituent elements identical or equivalent to those in the power converter 100 are denoted by like reference numerals and detailed description thereof will be omitted.

The load compensation information is information relating to the weight of each of one or more railway vehicles included in a train. The control unit 8B receives the load compensation information as passenger-load-factor information. By using the load compensation information, the passenger load factor of each vehicle in the train can be obtained by calculation. The calculation unit 81B generates the control voltage on the basis of the speed information, the notch information, the temperature information, and the passenger-load-factor information. Note that the torque command value may be used instead of the notch information. In this case, the calculation unit 81B generates the control voltage on the basis of the speed information, the torque command value, the temperature information, and the passenger-load-factor information.

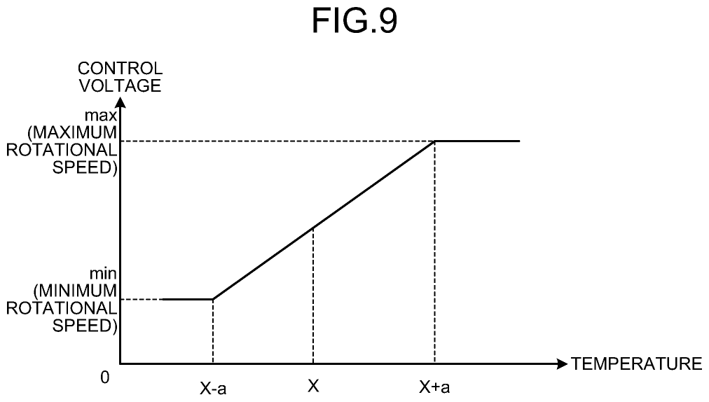

Next, operation of a main portion in the third embodiment will be described with reference to FIGS. 8 and 9. FIG. 8 is a first diagram provided for describing operation of the calculation unit 81B in the third embodiment. FIG. 9 is a second diagram provided for describing the operation of the calculation unit 81B in the third embodiment.

The calculation unit 81B includes a summing processing block 82 and a set temperature reference table 83. The set temperature reference table 83 is a reference table for outputting a passenger-load-factor-dependent temperature on the basis of the passenger load factor. As illustrated in FIG. 8, the passenger-load-factor-dependent temperature is set to be higher as the passenger load factor increases, and to be lower as the passenger load factor decreases. In the summing processing block 82, the initial temperature and the passenger-load-factor-dependent temperature are summed, and a value obtained as a result of the sum is output as a target balanced temperature X.

FIG. 9 illustrates a concept in which the control voltage applied to the cooling blower 34 is determined by the target balanced temperature X. In the example in FIG. 9, the target balanced temperature X is set to a median value of a temperature range, and temperature X-a is made to correspond to the minimum rotational speed and temperature X+a is made to correspond to the maximum rotational speed. That is, the target balanced temperature X is a reference temperature for defining a speed control range for the cooling blower 34.

In general, in the train operation, the motor torque is changed according to variation in passenger load factor of each vehicle, so that the amount of heat generated by the switching elements also varies according to the passenger load factor. Therefore, by making the temperature range within which rotational speed is variable follow the passenger load factor, the temperature fluctuation range due to the variation in passenger load factor can be reduced. As a result, an effect can be obtained that the heat stress that the switching elements are subjected to can be reduced.

Note that, in the example in FIG. 9, the target balanced temperature X is set to the median value of the temperature range, but the present disclosure is not limited to this example. The target balanced temperature X may be any set value as long as the value is between the upper limit value and the lower limit value of the temperature range.

As has been described above, according to the power converter for a railway vehicle of the third embodiment, the control unit determines the reference temperature for defining the speed control range for the cooling blower on the basis of the initial value of the temperature information and the passenger-load-factor information. The control unit defines the speed control range on the basis of the reference temperature, and controls the rotational speed of the cooling blower within the speed control range. The amount of heat generated by the switching elements also varies according to the passenger load factor. Therefore, by defining the speed control range for the cooling blower on the basis of the passenger-load-factor information, the temperature fluctuation range due to the variation of the passenger load factor can be reduced. As a result, as compared with the first and second embodiments, the life of the switching elements can be further extended.

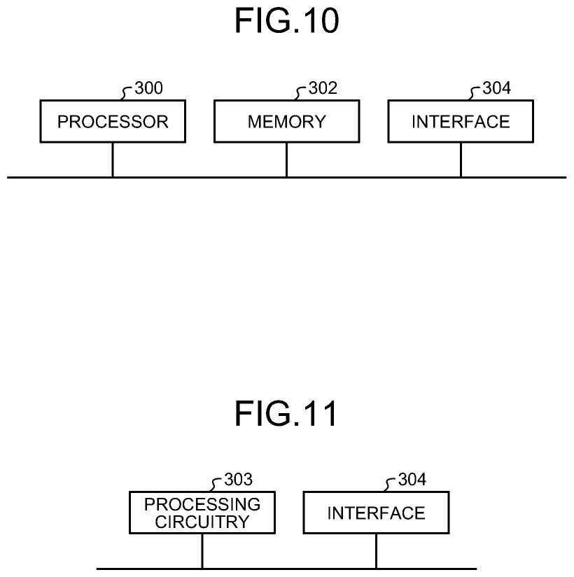

Finally, a hardware configuration for implementing functions of the above-described control units 8, 8A, and 8B will be described with reference to the drawings of FIGS. 10 and 11. FIG. 10 is a block diagram illustrating an example of the hardware configuration that implements the functions of the control units 8, 8A, and 8B in the first to third embodiments. FIG. 11 is a block diagram illustrating another example of the hardware configuration that implements the functions of the control units 8, 8A, and 8B in the first to third embodiments.

In a case where some or all of the functions of the control units 8, 8A, and 8B in the first to third embodiments are implemented, a configuration including a processor 300, a memory 302, and an interface 304 can be used as illustrated in FIG. 10. The processor 300 performs a calculation. The memory 302 stores a program read by the processor 300. Signals are input and output through the interface 304.

The processor 300 is a calculation means. The processor 300 may be a calculation means called a microprocessor, a microcomputer, a central processing unit (CPU), or a digital signal processor (DSP). In addition, examples of the memory 302 include a nonvolatile or volatile semiconductor memory such as a random access memory (RAM), a read only memory (ROM), a flash memory, an erasable programmable ROM (EPROM), or an electrically EPROM (EEPROM (registered trademark)), a magnetic disk, a flexible disk, an optical disk, a compact disk, a mini disk, and a digital versatile disc (DVD).

The memory 302 stores the program for executing the functions of the control units 8, 8A, and 8B in the first to third embodiments. The processor 300 can perform the above processing by transmitting and receiving necessary information via the interface 304, executing the program stored in the memory 302, and referring to a table stored in the memory 302. The calculation result by the processor 300 can be stored in the memory 302.

In addition, in a case where some of the functions of the control units 8, 8A, and 8B in the first to third embodiments are implemented, processing circuitry 303 illustrated in FIG. 11 can also be used. The processing circuitry 303 corresponds to a single circuit, a composite circuit, an application specific integrated circuit (ASIC), a field-programmable gate array (FPGA), or a combination thereof. Information input to the processing circuitry 303 and information output from the processing circuitry 303 can be obtained via the interface 304.

Note that some of the processes to be performed in the control units 8, 8A, and 8B may be performed by the processing circuitry 303, and processes not performed by the processing circuitry 303 may be performed by the processor 300 and the memory 302.

The configurations described in the above embodiments are just examples and can be combined with other known techniques. The embodiments can be combined with each other and the configurations can be partially omitted and/or modified without departing from the scope of the present disclosure.

### REFERENCE SIGNS LIST

2, 2A input circuit unit; 3, 3A inverter; 6 driving motor; 8, 8A, 8B control unit; 10 overhead contact line; 11 power collector; 12 rail; 13 wheel; 21 traction transformer; 22 converter; 23 filter capacitor; 31 power module; 32 cooler; 33 switching element; 34 cooling blower; 35 temperature sensor; 81, 81A, 81B calculation unit; 82 summing processing block; 83 set temperature reference table; 100, 100A, 100B power converter for railway vehicle; 300 processor; 302 memory; 303 processing circuitry; 304 interface.

1. A power converter for a railway vehicle to be installed in a railway vehicle and to perform required power conversion, the power converter comprising:
an inverter to convert direct-current power into alternating-current power for a driving motor; and
control circuitry to control operation of the inverter, wherein
the inverter includes:
a power module on which a plurality of switching elements are mounted;
a cooler to cool the power module; and
a cooling blower to supply cooling air to the cooler, and
the control circuitry controls rotational speed of the cooling blower on a basis of first information relating to an increase in temperature of the power module,
the first information is torque information relating to torque to be generated in the driving motor, and
the torque information is a torque command value to be used by the control circuitry or notch information to be indicated to the railway vehicle.

2. The power converter for a railway vehicle according to claim 1, wherein
the control circuitry stops rotation of the cooling blower when a train including one or more railway vehicles is in a coasting operation or in a stopped state.

3. (canceled)

4. (canceled)

5. A power converter for a railway vehicle to be installed in a railway vehicle and to perform required power conversion, the power converter comprising:
an inverter to convert direct-current power into alternating-current power for a driving motor; and
control circuitry to control operation of the inverter, wherein
the inverter includes:
a power module on which a plurality of switching elements are mounted;
a cooler to cool the power module;
a cooling blower to supply cooling air to the cooler; and
a temperature sensor to detect a temperature of the power module or the cooler
the control circuitry controls rotational speed of the cooling blower on a basis of first information relating to an increase in temperature of the power module,
the first information is temperature information detected by the temperature sensor, and
the control circuitry determines a change rate at a time of increasing or decreasing the rotational speed of the cooling blower on a basis of an initial value of the temperature information.

6. A power converter for a railway vehicle to be installed in a railway vehicle and to perform required power conversion, the power converter comprising:
an inverter to convert direct-current power into alternating-current power for a driving motor; and
control circuitry to control operation of the inverter, wherein
the inverter includes:
a power module on which a plurality of switching elements are mounted;
a cooler to cool the power module;
a cooling blower to supply cooling air to the cooler; and
a temperature sensor to detect a temperature of the power module or the cooler.
passenger-load-factor information relating to passenger load factor of each of one or more railway vehicles included in a train is input to the control circuitry,
the control circuitry controls rotational speed of the cooling blower on a basis of first information relating to an increase in temperature of the power module,
the first information is temperature information detected by the temperature sensor, and
the control circuitry determines a reference temperature for defining a speed control range for the cooling blower on a basis of an initial value of the temperature information and the passenger-load-factor information.

7. The power converter for a railway vehicle according to claim 1, comprising
a converter to generate the direct-current power and to supply the direct-current power to the inverter, wherein
the converter includes:
a second power module on which a plurality of switching elements are mounted;
a second cooler to cool the second power module; and
a second cooling blower to supply cooling air to the second cooler, and
the control circuitry controls rotational speed of the second cooling blower on a basis of second information relating to an increase in temperature of the second power module.

8. The power converter for a railway vehicle according to claim 2, comprising
a converter to generate the direct-current power and to supply the direct-current power to the inverter, wherein
the converter includes:
a second power module on which a plurality of switching elements are mounted;
a second cooler to cool the second power module; and
a second cooling blower to supply cooling air to the second cooler, and
the control circuitry controls rotational speed of the second cooling blower on a basis of second information relating to an increase in temperature of the second power module.

9. The power converter for a railway vehicle according to claim 5, comprising
a converter to generate the direct-current power and to supply the direct-current power to the inverter, wherein
the converter includes:
a second power module on which a plurality of switching elements are mounted;
a second cooler to cool the second power module; and
a second cooling blower to supply cooling air to the second cooler, and
the control circuitry controls rotational speed of the second cooling blower on a basis of second information relating to an increase in temperature of the second power module.

10. The power converter for a railway vehicle according to claim 6, comprising
a converter to generate the direct-current power and to supply the direct-current power to the inverter, wherein
the converter includes:
a second power module on which a plurality of switching elements are mounted;
a second cooler to cool the second power module; and
a second cooling blower to supply cooling air to the second cooler, and
the control circuitry controls rotational speed of the second cooling blower on a basis of second information relating to an increase in temperature of the second power module.
